(19) United States
(12) Patent Application Publication
(10) Pub. No.: US 2009/0242394 A1
(43) Pub. Date: Oct. 1, 2009

(54) AL-BASED ALLOY SPUTTERING TARGET AND MANUFACTURING METHOD THEREOF

(75) Inventors: Katsutoshi Takagi, Hyogo (JP); Yuki Iwasaki, Hyogo (JP); Masaya Ehira, Hyogo (JP); Hiroshi Goto, Hyogo (JP); Aya Miki, Hyogo (JP); Hiroyuki Okuno, Hyogo (JP); Mototaka Ochi, Hyogo (JP); Tomoya Kishi, Hyogo (JP)

Correspondence Address: OBLON, SPIVAK, MCCLELLAND MAIER & NEUSTADT, P.C., 1940 DUKE STREET, ALEXANDRIA, VA, 22314, US

(73) Assignees: KOBELCO RESEARCH INSTITUTE, INC., Kobe-shi (JP); Kabushiki Kaisha Kobe Seiko Sho(Kobe Steel, Ltd.), Kobe-shi (JP)

(21) Appl. No.: 12/414,877

(22) Filed: Mar. 31, 2009

(30) Foreign Application Priority Data
Mar. 31, 2008 (JP) 2008-093264

(51) Int. Cl. C23C 14/34; C21D 1/00

(52) U.S. Cl. 204/298.13; 148/537

(57) ABSTRACT

The present invention provides an Al—(Ni, Co)—(Cu, Ge)—(La, Gd, Nd) alloy sputtering target capable of decreasing a generation of splashing in an initial stage of using the sputtering target, preventing defects caused thereby in interconnection films or the like and improving a yield and operation performance of an FPD, as well as a manufacturing method thereof. The invention relates to an Al-based alloy sputtering target which is an Al—(Ni, Co)—(Cu, Ge)—(La, Gd, Nd) alloy sputtering target comprising at least one member selected from the group A (Ni, Co), at least one member selected from the group B (Cu, Ge), and at least one member selected from the group C (La, Gd, Nd) wherein a Vickers hardness (HV) thereof is 35 or more.

### CROSS-REFERENCE TO RELATED APPLICATIONS

This application claims priority from Japanese Patent Application No. 2008-093264 filed on Mar. 31, 2008, the entire subject matter of which is incorporated herein by reference.

### BACKGROUND OF THE INVENTION

1. Field of the Invention

The present invention relates to an Al-based alloy sputtering target containing at least one member selected from a group A (Ni, Co), at least one member selected from a group B (Cu, Ge), and at least one member selected from a group C (La, Gd, Nd), respectively (hereinafter referred to as “Al—(Ni, Co)—(Cu, Ge)—(La, Gd, Nd) alloy), and a manufacturing method thereof. Specifically the invention relates to an Al-based alloy sputtering target capable of decreasing initial splashing generated in an initial stage of sputtering upon depositing a thin film by using a sputtering target, and a manufacturing method thereof.

2. Description of the Related Art

Al-based alloys have been used generally with a reason of their low electrical resistivity and easy processability in the fields of flat panel displays (FPD) such as liquid crystal displays (LCD), plasma display panels (PDP), electroluminescence displays (ELD), field emission displays (FED), and micro electro mechanical systems (MEMS), touch panels, and electronic paper, and have been utilized as materials for interconnection films, electrode films, reflection electrode films, etc.

For example, an active matrix type liquid crystal display has a thin film transistor (TFT) as a switching device, a pixel electrode comprising a conductive oxide film, and a TFT substrate having interconnections including scanning lines and signal lines, in which the scanning lines and signal lines are electrically connected to the pixel electrodes. For interconnection materials constituting the scanning lines and the signal lines, thin films of pure Al or Al—Nd alloy have generally been used. However, in a case such thin films are in direct contact with pixel electrodes, since insulating aluminum oxides or the like are formed at their interface to increase electrical contact resistance, a barrier metal layer comprising a metal having a high melting point such as Mo, Cr, Ti or W is interposed between the interconnection material of Al and the pixel electrode for decreasing the electrical contact resistance.

However, the method of interposing the barrier metal layer as described above involves a problem of complicating manufacturing steps to increase the production cost.

Then, for providing a technique capable of direct contact between a conductive oxide film constituting a pixel electrode and an interconnection material not by way of a barrier metal layer (direct contact technique), a method of using a thin film of Al—Ni alloys, or Al—Ni-rare earth element alloys that further contain a rare earth element such as Nd or Y has been proposed (JP-A-2004-214606) as the interconnection material. By using the Al—Ni alloy, since Ni-containing conductive precipitates or the like are formed at the interface to suppress the formation of insulating aluminum oxides or the like, the electrical contact resistance can be kept lower. Further, in a case of using the Al—Ni-rare earth element alloys, heat resistance is further enhanced.

By the way, for forming an Al-based alloy film, a sputtering method of using a sputtering target has been adopted generally. The sputtering method is a method of forming plasma discharge between a substrate and a sputtering target made of a material identical with the thin film material, colliding a gas ionized by the plasma discharge against the sputtering target thereby ejecting atoms of the sputtering target, and depositing them on the substrate to prepare a thin film.

Different from a vacuum vapor deposition method, the sputtering method has an advantage capable of forming a thin film of a composition identical with that of a sputtering target. Particularly, since an alloy element such as Nd which is not dissolved in an equilibrium can dissolve in the Al-based alloy film formed by the sputtering method and the Al-based alloy film provides an excellent performance as a thin film, this is an industrially effective method of preparing a thin film and development has been proceeded for the sputtering target as the material therefor.

In recent years, for coping with the increase of the productivity of FPD or the like, the depositing rate during sputtering step has tended to be increased than usual. For increasing the depositing rate, it is most convenient to increase a sputtering power. However, when the sputtering power is increased, since sputtering failure such as splashing (fine molten particles) is generated to result in defects in interconnection films or the like, this gives a drawback such as lowering of the yield and operation performance of FPD.

Then, with an aim of preventing the generation of the splashing, methods described, for example in JP-A-10-147860, JP-A-10-199830, JP-A-11-293454 and JP-A-2001-279433, have been proposed. Among them, each of JP-A-10-147860, JP-A-10-199830, and JP-A-11-293454 is based on the view that the splashing is caused by fine voids in the structure of a sputtering target and intends to prevent the generation of the splashing by controlling a dispersion state of compound particles of Al and rare earth element in an Al matrix (JP-A-10-147860), controlling the dispersion state of a compound of Al and a transition element in the Al matrix (JP-A-10-199830), or controlling the dispersion state of an intermetallic compound of an additive element and Al in a sputtering target (JP-A-11-293454). Further, JP-A-2001-279433 discloses a method of suppressing the generation of surface defects accompanying machining by adjusting the hardness of a sputtered surface and then performing finishing machining for decreasing arcing (abnormal discharge) that causes the splashing.

On the other hand, as the technique of preventing the generation of the splashing, JP-A-9-235666 describes rolling an ingot mainly comprising Al in a temperature range from 300 to 450° C. at a working ratio of 75% or less into a plate shape, then applying a heat treatment at a temperature of a rolling temperature or higher and 550° C. or lower and forming a sputtering surface on the side of a rolled surface, thereby controlling the Vickers hardness of the obtained sputtering target such as an Al—Ti—W alloy to 25 or less.

### SUMMARY OF THE INVENTION

As has been described above, a countermeasure for preventing the splash is disclosed to some extent, for example, in Al—Ni-rare earth element alloys or Al—Ti—W alloys. However, it is considered that the splash preventive technique is different also depending on the kind of the sputtering target. The present inventors have already found that when an Al—(Ni, Co)—(Cu, Ge)—(La—Gd—Nd) alloy is used, the Al-based alloy film formed of the material and a pixel electrode comprising a conductive oxide film can be in direct contact with each other and, further, low electrical resistivity and excellent heat resistance can be obtained even in a case where the heating treatment temperature after contact is relatively low. However, a splash preventive countermeasure which is particularly effective in a case where the sputtering target is an Al—(Ni, Co)—(Cu, Ge)—(La, Gd, Nd) alloy has not yet been established.

In view of the above, the invention intends to provide a sputtering target capable of effectively preventing the splashing in a case of using the Al—(Ni, Co)—(Cu, Ge)—(La, Gd, Nd) alloy as a sputtering target, and a manufacturing method thereof.

The features of the invention are shown below.
(1) An Al-based alloy sputtering target comprising;

at least one element selected from the group A consisting of Ni and Co,

at least one element selected from the group B consisting of Cu and Ge, and

at least one element selected from the group C consisting of La, Gd, and Nd,

wherein a hardness of the Al-based alloy sputtering target is 35 or more as a Vickers hardness (HV).
(2) The Al-based alloy sputtering target according to (1), wherein

a total content of the group A is 0.05 atomic % or more and 1.5 atomic % or less,

a total content of the group B is 0.1 atomic % or more and 1 atomic % or less, and

a total content of the group C is 0.1 atomic % or more and 1 atomic % or less.
(3) The Al-based alloy sputtering target according to (1), wherein only Ni is selected from the group A, only Cu is selected from the group B, and only La is selected from the group C.
(4) The Al-based alloy sputtering target according to (2), wherein only Ni is selected from the group A, only Cu is selected from the group B, and only La is selected from the group C.
(5) A method of manufacturing an Al-based alloy sputtering target comprising:

obtaining a molten metal at 850 to 1000° C. of an Al-based alloy comprising:

a group A consisting of Ni and Co in a total amount of 0.05 atomic % or more and 1.5 atomic % or less,

a group B consisting of Cu and Ge in a total amount of 0.1 atomic % or more and 1 atomic % or less, and

a group C consisting of La, Gd, and Nd in a total amount of 0.1 atomic % or more and 1 atomic % or less;

gas-atomizing the molten metal at a gas/metal ratio of 6 Nm³/kg or more to refine the Al-based alloy;

depositing the refined Al-based alloy on a collector under a condition of a spray distance of from 900 to 1200 mm to obtain a perform;

densifying the preform by a densifying means to obtain a dense body;

subjecting the dense body to plastic working at 450° C. or lower; and

subjecting the dense body after plastic working to heat treatment or annealing at 100 to 300° C.
(6) The method of manufacturing an Al-based alloy sputtering target according to (5), wherein only Ni is selected from the group A, only Cu is selected from the group B, and only La is selected from the group C.
(7) The Al-based alloy sputtering target according to (1), wherein only Co is selected from the group A, only Ge is selected from the group B, and only La is selected from the group C.
(8) The Al-based alloy sputtering target according to (2), wherein only Co is selected from the group A, only Ge is selected from the group B, and only La is selected from the group C.
(9) The method of manufacturing an Al-based alloy sputtering target according to (5), wherein only Co is selected from the group A, only Ge is selected from the group B, and only La is selected from the group C.
(10) The Al-based alloy sputtering target according to (1), wherein only Ni is selected from the group A, only Ge is selected from the group B, and only Nd is selected from the group C.
(11) The Al-based alloy sputtering target according to (2), wherein only Ni is selected from the group A, only Ge is selected from the group B, and only Nd is selected from the group C.
(12) The method of manufacturing an Al-based alloy sputtering target according to (5), wherein only Ni is selected from the group A, only Ge is selected from the group B, and only Nd is selected from the group C.
(13) The Al-based alloy sputtering target according to (1), wherein only Co is selected from the group A, only Ge is selected from the group B, and only Nd is selected from the group C.
(14) The Al-based alloy sputtering target according to (2), wherein only Co is selected from the group A, only Ge is selected from the group B, and only Nd is selected from the group C.
(15) The method of manufacturing an Al-based alloy sputtering target according to (5), wherein only Co is selected from the group A, only Ge is selected from the group B, and only Nd is selected from the group C.

According to the invention, since the Al—(Ni, Co)—(Cu, Ge)—(La, Gd, Nd) alloy is used as the sputtering target and the Vickers hardness (HV) of the sputtering target is appropriately controlled, generation of abnormal discharge in the initial stage, particularly, generation of initial splashing at the initial stage of using the sputtering target is decreased. Accordingly, defects generated in interconnection films or the like by the splashing can be prevented and, as a result, yield of FPD can be improved and the operation performance of FPD can be improved.

### BRIEF DESCRIPTION OF THE DRAWINGS

FIG. 1 is a fragmentary cross sectional view for an example of an apparatus used for manufacturing a preform according to an embodiment of the invention.

FIG. 2 is an enlarged view for a main portion of X shown in FIG. 1.

### EXPLANATION OF REFERENCES

1 Induction melting furnace
2 Molten metal of Al-based alloy
3a, 3b Gas atomizer
4a, 4b Gas hole of bobbin
5 Collector
6 Nozzle
6a, 6b Center axis for gas atomizer nozzle
A Spray axis
A1 End of nozzle 6
A2 Center of collector 5
A3 Intersection between horizontal line for center A2 of collector 5 and spray axis A
L Spray distance
α Exit angle of gas atomizer
β Collector angle

### DETAILED DESCRIPTION OF THE INVENTION

The inventors have made earnest studies on the situation in the generation of splashing under various conditions in order to decrease the sputtering failure when using an Al—(Ni, Co)—(Cu, Ge)—(La, Gd, Nd) alloy sputtering target. As a result, it has been found that the generation of the splashing is decreased remarkably by increasing the Vickers hardness (HV) of the sputtering target, and the inventors have further investigated a manufacturing method and manufacturing conditions of an Al-based alloy sputtering target capable of suppressing the generation of the splashing, thereby accomplishing the invention.

More specifically, studies have been made as described below. In a case where the hardness of the Al—(Ni, Co)—(Cu, Ge)—(La, Gd, Nd) alloy sputtering target is low, the initial splashing tends to be generated. The followings may be considered, for example, for the reason. That is, in a case where the hardness of the sputtering target is low, since micro smoothness on the finished surface machined by a milling cutter, a lathe or the like used for the manufacture of the sputtering target is worsened, that is, since the material surface is deformed in a complicate manner and roughened, contaminants such as cutting oils used for the machining are taken to and remained on the surface of the sputtering target. Such contaminants are difficult to be removed sufficiently even by surface cleaning in the subsequent step. As described above, it is considered that the contaminants remaining on the surface of the sputtering target form trigger points of the initial splashing during sputtering.

In order not to leave such contaminants on the surface of the sputtering target, it is necessary to improve the workability upon machining so that the material surface is not roughened. Therefore, the inventors considered to increase the hardness of the sputtering target.

In the invention, the hardness of the Al—(Ni, Co)—(Cu, Ge)—(La, Gd, Nd) alloy sputtering target is defined to 35 or more by Vickers hardness (HV). This is because the surface after machining is roughened to increase the initial splashing in a case where the Vickers hardness is less than 35. Accordingly, the Vickers hardness is adjusted to 35 or more, more preferably 40 or more, and further preferably 45 or more. There is no particular restriction for the upper limit value of the Vickers hardness. However, when the hardness is excessively high, since plastic working such as forging or rolling is difficult to be applied, the Vickers hardness is preferably 160 or less, more preferably 140 or less, and further preferably 120 or less.

The present applicant has hitherto proposed a technique regarding an Al-based alloy film such as an interconnection film, an electrode film, or a reflection electrode film formed by using an Al-based alloy sputtering target, capable of bringing the film into direct contact with a conductive oxide film that constitutes a pixel electrode at a low electrical contact resistance. Such a technique is used preferably as “direct contact technique” as described above. The group A (Ni, Co) contained in the Al-based alloy sputtering target of the invention is an effective element for decreasing the electrical contact resistance between the Al-based alloy film and a pixel electrode in direct contact with the Al-based alloy film, and one or more elements thereof are incorporated thereinto.

The total content of the group A is preferably from 0.05 to 1.5 atomic %. The total content is defined as 0.05 atomic % or more for providing the effect of decreasing the electrical contact resistance further effectively. It is more preferably 0.07 atomic % or more, and further preferably 0.1 atomic % or more. On the other hand, in a case where the total content of the group A is excessively large, since the electrical resistivity of the Al-based alloy film is increased, it is preferably 1.5 atomic % or less. It is more preferably 1.3 atomic % or less and further preferably 1.1 atomic % or less.

The group B (Cu, Ge) contained in the Al-based alloy sputtering target of the invention is an effective element for improving the corrosion resistance of the Al-based alloy film formed by using the Al-based alloy sputtering target, and one or more elements thereof are incorporated thereinto.

The total content of the group B is preferably from 0.1 to 1 atomic %. The total content is defined as 0.1 atomic % or more for providing the effect of corrosion resistance further effectively. It is more preferably 0.2 atomic % or more, and further preferably 0.3 atomic % or more. On the other hand, in a case where the total content of the group B is excessively large, since the electrical resistivity of the Al-based alloy film is increased, it is preferably 1 atomic % or less. It is more preferably 0.8 atomic % or less and further preferably 0.6 atomic % or less.

The group C (La, Gd, Nd) contained in the Al-based alloy sputtering target of the invention is an effective element for improving the heat resistance of the Al-based alloy film formed by using the Al-based alloy sputtering target, thereby preventing hillock formed on the surface of the Al-based alloy film, and one or more elements thereof are incorporated thereinto.

The total content of the group C is preferably from 0.1 to 1 atomic %. The total content is defined as 0.1 atomic % or more for providing the effect of heat resistance, that is, the effect of preventing the hillock further effectively. It is more preferably 0.2 atomic % or more, and further preferably 0.3 atomic % or more. On the other hand, in a case where the total content of the group C is excessively large, since the electrical resistivity of the Al-based alloy film is increased, it is preferably 1 atomic % or less. It is more preferably 0.8 atomic % or less and further preferably 0.6 atomic % or less.

The Al-based alloy used in the invention comprises at least one member selected from the group A (Ni, Co), at least one member selected from the group B (Cu, Ge), and at least one member selected from the group C (La, Gd, Nd), and a reminder comprises Al and inevitable impurities. The inevitable impurities include those elements intruding inevitably in the manufacturing process or the like, for example, Fe, Si, C, O, and N. The content is preferably controlled to be 0.05 wt. % or less of Fe, 0.05 wt. % or less of Si, 0.05 wt. % or less of C, 0.05 wt. % or less of O and 0.05 wt. % or less of N.

Then, the outline for the method of manufacturing the sputtering target of the invention is to be described.

At first, a molten metal of an Al—(Ni, Co)—(Cu, Ge)—(La, Gd, Nd) alloy is prepared.

Then, after manufacturing a perform of the Al-based alloy (intermediate body before obtaining a final dense body) by a spray forming method by using the Al-based alloy described above, the preform is densified by densifying means.

The spray forming method is a method of atomizing various kinds of molten metals by a gas, depositing particles quenched to a semi-molten state, a semi-solidification state, and a solid state, and obtaining a base material (preform) of a given shape. The method provides an advantage, for example, capable of obtaining, in a single step, a large sized preform which is difficult to obtain by a melt casting method, a powder sintering method or the like, as well as capable of finely refining crystal grains and uniformly dispersing the alloy elements.

The manufacturing step for the preform includes a step of obtaining a molten metal of an Al-based alloy by melting generally within a range from (liquid phase temperature +150° C.) to (liquid phase temperature +300° C.), a step of refining the molten metal of the Al-based alloy by gas-atomizing under the condition at a gas/metal ratio represented by the ratio of gas flowing amount/molten metal flowing amount of 6 Nm³/kg or more, and a step of depositing the refined Al-based alloy on a collector under the condition of a spray distance of about 900 to 1200 mm, thereby obtaining a preform.

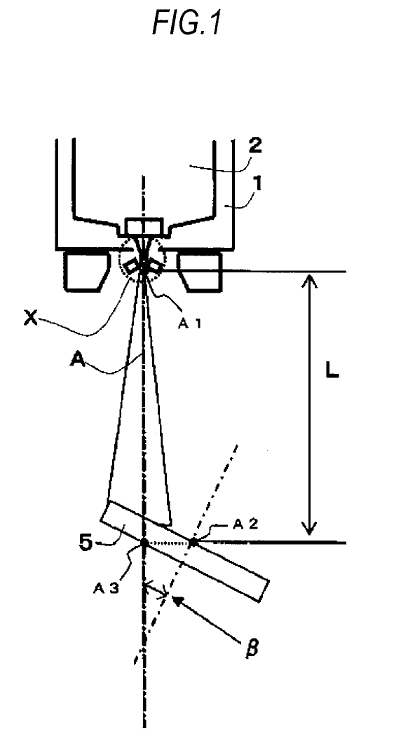

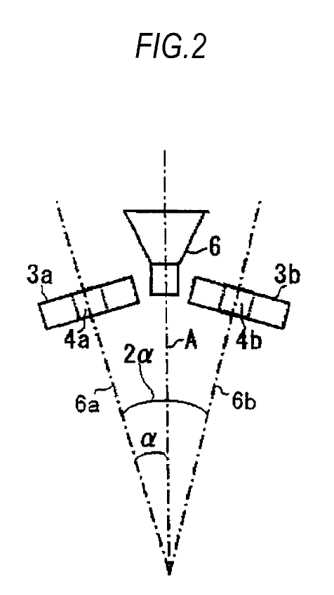

Each of the steps for obtaining the preform is to be described specifically with reference to FIG. 1 and FIG. 2.

FIG. 1 is a fragmentary cross sectional view for an example of an apparatus used for manufacturing the preform of the invention. FIG. 2 is an enlarged view for a main portion X in FIG. 1.

With reference to the schematic cross sectional view of the apparatus shown in FIG. 1 and an enlarged explanatory view for a main portion of a gas jetting portion shown in FIG. 2, the apparatus has an induction melting furnace 1 for melting an Al-based alloy, gas atomizers 3a and 3b disposed below the induction melting furnace 1 respectively, and a collector 5 for depositing the preform. The induction melting furnace 1 has a nozzle 6 for dropping the molten metal 2 of the Al-based alloy. Further, the gas atomizers 3a and 3b have gas holes 4a and 4b of bobbins respectively for atomizing the gas. The collector 5 has driving means such as a stepping motor (not illustrated) for lowering the collector 5 such that the height for the preform deposition surfaces is constant even when manufacture of the preform proceeds.

At first, the Al-based alloy of the composition described above is prepared. After adding the Al-based alloy into the induction melting furnace 1, it is melted, preferably, in an inert gas atmosphere (for example, Ar gas) at a temperature within a range of about +150° C. to +300° C. relative to the liquid phase temperature of the Al-based alloy.

The melting temperature is generally set within a range from the liquid phase temperature +50° C. to the liquid phase temperature +200° C. (for example, refer to JP-A-9-248665). On the other hand, in the method of manufacturing the Al-based alloy sputtering target, the melting temperature is set to the range of from the liquid phase temperature +150° C. to +300° C. in the invention for properly controlling the grain size distribution of the intermetallic compounds. In the case of Al—(Ni, Co)—(Cu, Ge)—(La, Gd, Nd) alloy as an object of the invention, it is melted at a temperature generally from 850 to 1000° C. In a case where the melting temperature is lower than 850° C., the nozzle is clogged in the spray forming.

On the other hand, in a case where the temperature exceeds 1000° C., since the temperature of the droplet increases, the area ratio occupied by the intermetallic compound with an average grain size of 3 μm or more is increased, and no desired effect of decreasing the splashing can be obtained. The melting temperature of the Al-based alloy is preferably within a range from (liquid phase temperature +150C.) to (liquid phase temperature +300° C.). In a case of the Al—(Ni, Co)—(Cu, Ge)—(La, Gd, Nd) alloy as an object of the invention, it is preferably from 850 to 1000° C. and more preferably from 900 to 1000° C.

The method of manufacturing the Al-based alloy sputtering target of the invention includes a step of gas-atomizing and refining the molten metal of the Al-based alloy at a gas/metal ratio of 6 Nm³/kg or more.

Gas atomizing is preferably performed by using an inert gas or a nitrogen gas, by which oxidation of the molten metal is suppressed. The inert gas includes, for example, an argon gas.

In this case, the gas/metal ratio is set to 6 Nm³/kg or more. The gas/metal ratio is represented by the ratio of gas flowing amount (Nm³)/molten metal flowing amount (kg). In the present specification, the gas flowing amount means a total amount of a gas flowed from the gas holes 4a and 4b of the bobbins for gas-atomizing the molten metal of the Al-based alloy (amount used finally). Further, in the specification, the molten metal flowing amount means the total amount of the molten metal flowed from molten metal flow port (nozzle 6) of a vessel containing the molten metal of the Al-based alloy (induction melting furnace 1).

In a case where the gas/metal ratio is less than 6 Nm³/kg, since the size of the droplet tends to increase, the cooling rate is lowered and the occupation ratio of the intermetallic compound with the average grain size more than 3 μm is increased, no desired effect can be obtained.

A higher gas/metal ratio is more preferred. For example, it is preferably 6.5 Nm³/kg or more and more preferably 7 Nm³/kg or more. While the upper limit thereof is not particularly restricted, it is preferably 15 Nm³/kg or less and more preferably 10 Nm³/kg or less while considering the stability of the flow of droplet upon gas atomizing and the cost.

Assuming the angle formed between the opposed central axes 6a and 6b of the gas atomizer nozzle as 2α, 2α is preferably controlled within a range from 1 to 50° and more preferably 0 to 40°.

The method of manufacturing the Al-based alloy sputtering target of the invention includes a step of obtaining a preform by depositing the refined Al-based alloy on the collector under the condition of a spray distance of from 900 to 1200 mm.

The step is performed by depositing the Al-based alloy refined as described above (liquid droplet) on the collector 5 thereby obtaining a preform.

In this case, the spray distance is preferably controlled within a range from 900 to 1200 mm. The spray distance defines the accumulation position for the droplets and means a distance L from the end of the nozzle 6 (A1 in FIG. 1) to the center of the collector 5 (A2 in FIG. 1). As will be described later, since the collector 5 is slanted at a collector angle β, the spray distance L means, strictly, a distance between the end of the nozzle 6 and an intersection between the horizontal line for the center A2 of the collector 5 and the spray axis A (A3 in FIG. 1). The spray axis A defines a direction along which the droplet of the Al-based alloy drops just vertically below for the convenience of explanation.

Generally, while the spray distance in the spray forming is often controlled to about 500 mm, this is defined in this invention as within the range described above for obtaining a desired grain size distribution for the intermetallic compounds described above. In a case where the spray distance is less than 900 mm, since the droplet at a high temperature is deposited on the collector to lower the cooling rate and the occupation ratio of the intermetallic compound with the average grain size of 3 μm or more is increased, no desired effect can be obtained. On the other hand, in a case where the spray distance is more than 1200 mm, the yield is lowered. The spray distance L is more preferably within a range about from 950 to 1100 mm.

Further, the collector angle β is preferably controlled within a range from 20 to 45° and more preferably 30 to 40°.

The method of manufacturing the Al-based alloy sputtering target of the invention includes a step of densifying the preform by densifying means thereby obtaining a dense body.

As the densifying means, it is preferred to perform a method of pressurizing the preform substantially in an isotropic direction, particularly, perform hot isostatic pressing (HIP) in which pressurizing is performed in a hot state. Specifically, the HIP treatment is performed preferably under the pressure of 80 MPa or higher and more preferably 90 MPa or more and at a temperature of from 400 to 600° C. and more preferably from 500 to 570° C. The time for the HIP treatment is preferably within a range about from 1 to 10 hours and more preferably from 1.5 to 5 hours.

The method of manufacturing the Al-based alloy sputtering target of the invention includes a step of subjecting the dense body to plastic working at 450° C. or lower. The temperature is defined as 450° C. or lower, because the crystal grains of the Al matrix and the intermetallic compounds in the Al matrix are grown when the temperature exceeds 450° C. to lower the hardness, and the number of generation of the initial splashing is increased. Accordingly, the temperature for plastic working of the dense body is preferably 450° C. or lower, more preferably 420° C. or lower, and further preferably 400° C. or lower.

The method of manufacturing the Al-based sputtering target of the invention includes a step of subjecting the dense body to the heat treatment or annealing at 100° C. to 300° C. after plastic working. Heat treatment or annealing is applied in order to eliminate strains in the dense body caused by the plastic working.

The temperature of the heat treatment or annealing is defined as 100° C. or higher, because strains caused by plastic working cannot be removed by heat treatment or annealing when the temperature is lower than 100° C. thereby making it difficult to finish the product to have a desired size and shape by machining in the subsequent step.

The temperature of the heat treatment or annealing is preferably 150° C. or higher and more preferably 200° C. or higher. On the other hand, in a case where the temperature of the heat treatment or annealing exceeds 300° C., crystal grains of the Al matrix and the intermetallic compounds in the Al matrix are grown to lower the hardness, and the number of generation of the initial splashing is increased. Accordingly, the upper limit of the temperature of the heat treatment or annealing is preferably 300° C. It is more preferably 270° C. or lower and more preferably 250° C. or lower. Further, the time of the heat treatment or annealing is, for example, 1 to 4 hours, and preferably 2 to 3 hours.

According to the method of manufacturing the Al-based alloy sputtering target described above, although the amount of the alloy elements in the Al—(Ni, Co)—(Cu, Ge)—(La, Gd, Nd) alloy (the total amount of elements selected from the group A, the group B, and the group C) is small, hardness can be increased highly by precipitation hardening due to fine and uniform precipitation of the intermetallic compounds in the Al matrix and, further, strengthening of crystal grain boundary by refining and uniforming the crystal grains of the Al matrix. Then, in the invention, for finely and uniformly precipitating the intermetallic compounds in the Al matrix, not a melt-casting method but a spray forming method as one kind of quenching method is used for the manufacturing method. Further, for making the crystal grains of the Al matrix fine and uniform, plastic working under a controlled temperature and heat treatment or annealing under a controlled temperature are adopted for the manufacturing method.

### EXAMPLE

The invention is to be described more specifically with reference to examples but the invention is not restricted to the following examples and can be practiced with appropriate modifications in a range capable of conforming to the gist of the invention that has been described previously and to be described later, and all of them are contained within the technical range of the invention.

### Example 1

Al-based alloy preforms (density: about 50 to 60%) were obtained by a spray forming method using Al—Ni—Cu—La alloys under various conditions as shown in Tables 1 and2.

### (Spray Forming Conditions)

Melting temperature: 800 to 1100° C. (refer to Tables 1 and 2)
Gas/metal ratio: 5 to 8 Nm³/kg (refer to Tables 1 and 2)
Spray distance: 800 to 1300 mm (refer to Tables 1 and 2)
Exit angle α of gas atomizer (refer to FIG. 2): 7°
Collector angle β: 35°

The thus obtained preform was encapsulated and degassed in a capsule and hot isostatic pressing (HIP) was performed to the entire capsule to obtain a dense body of an Al—Ni—Cu—La alloy. The HIP treatment was performed at an HIP temperature of 550° C., at an HIP pressure of 85 MPa, and for an HIP time of 2 hours.

Then, after forging the obtained dense body into a plate-like metal material and, further, rolling the same such that the plate thickness was mostly identical with that of a final product (sputtering target), it was subjected to heat treatment or annealing and machining (cutting and lathing working) to manufacture a disk-like Al—Ni—Cu—La alloy sputtering target (size: 101.6-mm diameter×5.0-mm thickness). Details conditions for the plastic working or the like are as shown below.
Heating condition before forging: at 500° C. for 2 hours
Heating condition before rolling: at 350 to 480° C. for 2 hours
Total reduction ratio: 50%
Condition of heat treatment or annealing: at 50 to 350° C. for 2 hours

The Vickers hardness (HV) of the manufactured specimen was measured by using a Vickers hardness apparatus (AVK-G2, manufactured by Akashi Seisakusho, Ltd.).

Then, by using each of the sputtering targets obtained by the method described above, the number of the splashing (initial splashing) generated upon performing sputtering under the following conditions was measured.

At first, to an Si wafer substrate (size: 100.0-mm diameter×0.50-mm thickness), DC magnetron sputtering was performed by using a sputtering apparatus of “sputtering system HSR-542S” manufactured by Shimadzu Corporation. The sputtering conditions are as described below.
Back pressure: 3.0×10⁻⁶ Torr or less,
Ar gas pressure: 2.25×10⁻³ Torr,
Ar gas flow rate: 30 sccm,
Sputtering power: 811 W,
Distance between a substrate and a sputtering target: 51.6 mm,
Substrate temperature: room temperature
Sputtering time: 81 sec

As described above, 16 sheets of thin films were formed per one piece of a sputtering target. Accordingly, sputtering was performed for 81 (sec)×16 (sheets)=1296 sec.

Then, by using a particle counter (wafer surface inspection apparatus WM-3, manufactured by Topcon Corporation), the positional coordinate, the size (average particle size), and the number of particles observed on the surface of the thin film were measured. In this case, those of a size of 3 μm or more were regarded as particles. Then, the thin film surface was observed by an optical microscope at a magnification of 1000, those of a semi-spherical shape were regarded as the splashing and the number of the splashing per unit area was counted.

Specifically, the step of performing the sputtering described above for one sheet of the thin film was conducted continuously for 16 sheets of thin films in the same manner while replacing the Si wafer substrates, and the average value for the number of the splashing was defined as “number of generation of initial splashing”. In this example, those with the number of generation of the initial splashing of less than 8 Number/cm² obtained as described above were defined as “having effect of decreasing initial splashing; pass (A)”, while those of 8 Number/cm² or more were defined as “having no effect of decreasing initial splashing: failed (B)”. The test results are shown in Tables 1 and 2 (Nos. 1 to 33). For Nos. 6, 9, 13, 19, 22, 26, and 31, specimens of the composition identical with that for No. 3 were used.

TABLE 1

| | | | | | | | | | | Number of | |
|---|---|---|---|---|---|---|---|---|---|---|---|
| | | | | | | | | Temperature | | generation | Pass/failure |
| | | | | | | | | of heat | | of initial | judgment for |
| | | | | Melting | Gas/Metal | Spray | Rolling | treatment or | Vickers | splashing | decreasing |
| | Ni | Cu | La | temperature | ratio | distance | temperature | annealing | hardness | (Number/ | initial |
| No. | (at %) | (at %) | (at %) | (° C.) | (Nm³/kg) | (mm) | (° C.) | (° C.) | (HV) | cm²) | splashing |
| 1 | 0.05 | 0.5 | 0.3 | 950 | 8 | 1000 | 400 | 250 | 39.4 | 7 | A |
| 2 | 0.6 | 0.5 | 0.3 | 950 | 8 | 1000 | 400 | 250 | 49.2 | 3 | A |
| 3 | 1.0 | 0.5 | 0.3 | 950 | 8 | 1000 | 400 | 250 | 49.4 | 3 | A |
| 4 | 1.5 | 0.5 | 0.3 | 950 | 8 | 1000 | 400 | 250 | 50.8 | 2 | A |
| 5 | 1.0 | 0.1 | 0.3 | 950 | 8 | 1000 | 400 | 250 | 48.9 | 3 | A |
| 6 | 1.0 | 0.5 | 0.3 | 950 | 8 | 1000 | 400 | 250 | 49.4 | 3 | A |
| 7 | 1.0 | 1.0 | 0.3 | 950 | 8 | 1000 | 400 | 250 | 53.7 | 2 | A |
| 8 | 1.0 | 0.5 | 0.1 | 950 | 8 | 1000 | 400 | 250 | 49.1 | 4 | A |
| 9 | 1.0 | 0.5 | 0.3 | 950 | 8 | 1000 | 400 | 250 | 49.4 | 3 | A |
| 10 | 1.0 | 0.5 | 1.0 | 950 | 8 | 1000 | 400 | 250 | 54.4 | 1 | A |
| 11 | 1.0 | 0.5 | 0.3 | 800 | | 1000 | | | | | |
| 12 | 1.0 | 0.5 | 0.3 | 850 | 8 | 1000 | 400 | 250 | 49.7 | 3 | A |
| 13 | 1.0 | 0.5 | 0.3 | 950 | 8 | 1000 | 400 | 250 | 49.4 | 3 | A |
| 14 | 1.0 | 0.5 | 0.3 | 1000 | 8 | 1000 | 400 | 250 | 49.2 | 4 | A |
| 15 | 1.0 | 0.5 | 0.3 | 1100 | 8 | 1000 | 400 | 250 | 33.3 | 18 | B |
| 16 | 1.0 | 0.5 | 0.3 | 950 | 5 | 1000 | 400 | 250 | 32.5 | 23 | B |
| 17 | 1.0 | 0.5 | 0.3 | 950 | 6 | 1000 | 400 | 250 | 47.9 | 4 | A |
| 18 | 1.0 | 0.5 | 0.3 | 950 | 7 | 1000 | 400 | 250 | 48.8 | 4 | A |
| 19 | 1.0 | 0.5 | 0.3 | 950 | 8 | 1000 | 400 | 250 | 49.4 | 3 | A |

TABLE 2

| | | | | | | | | | | Number of | |
|---|---|---|---|---|---|---|---|---|---|---|---|
| | | | | | | | | Temperature | | generation | Pass/failure |
| | | | | | | | | of heat | | of initial | judgment for |
| | | | | Melting | Gas/Metal | Spray | Rolling | treatment or | Vickers | splashing | decreasing |
| | Ni | Cu | La | temperature | ratio | distance | temperature | annealing | hardness | (Number/ | initial |
| No. | (at %) | (at %) | (at %) | (° C.) | (Nm³/kg) | (mm) | (° C.) | (° C.) | (HV) | cm²) | splashing |
| 20 | 1.0 | 0.5 | 0.3 | 950 | 8 | 800 | 400 | 250 | 34.1 | 15 | B |
| 21 | 1.0 | 0.5 | 0.3 | 950 | 8 | 900 | 400 | 250 | 49.9 | 2 | A |
| 22 | 1.0 | 0.5 | 0.3 | 950 | 8 | 1000 | 400 | 250 | 49.4 | 3 | A |
| 23 | 1.0 | 0.5 | 0.3 | 950 | 8 | 1200 | 400 | 250 | 49.0 | 3 | A |
| 24 | 1.0 | 0.5 | 0.3 | 950 | 8 | 1300 | | | | | |
| 25 | 1.0 | 0.5 | 0.3 | 950 | 8 | 1000 | 350 | 250 | 50.9 | 2 | A |
| 26 | 1.0 | 0.5 | 0.3 | 950 | 8 | 1000 | 400 | 250 | 49.4 | 3 | A |
| 27 | 1.0 | 0.5 | 0.3 | 950 | 8 | 1000 | 450 | 250 | 48.2 | 4 | A |
| 28 | 1.0 | 0.5 | 0.3 | 950 | 8 | 1000 | 480 | 250 | 31.6 | 26 | B |
| 29 | 1.0 | 0.5 | 0.3 | 950 | 8 | 1000 | 400 | 50 | 52.9 | | |
| 30 | 1.0 | 0.5 | 0.3 | 950 | 8 | 1000 | 400 | 100 | 52.1 | 2 | A |
| 31 | 1.0 | 0.5 | 0.3 | 950 | 8 | 1000 | 400 | 250 | 49.4 | 3 | A |
| 32 | 1.0 | 0.5 | 0.3 | 950 | 8 | 1000 | 400 | 300 | 48.5 | 3 | A |
| 33 | 1.0 | 0.5 | 0.3 | 950 | 8 | 1000 | 400 | 350 | 32.8 | 22 | B |

In Tables 1 and 2, contents of elements are shown as Ni (at %) for the content of Ni element (atomic %), as Cu (at %) for the content of Cu element (atomic %), and as La (at %) for the content of La element (atomic %), respectively. From Tables 1 and 2, the followings can be recognized. In Nos. 1 to 10, 12 to 14, 17 to 19, 21 to 23, 25 to 27, 30 to 32, since the Vickers hardness (HV) of the Al—Ni—Cu—La alloy sputtering target is controlled properly, the number of generation of the initial splashing remains to less than 8 Number/cm² and they have an effect of decreasing the initial splashing.

On the contrary, in the specimens having not appropriate Vickers hardness (HV), the number of generation of the splashing is 8 Number/cm² or more by the following reason respective and it cannot be said that they have the effect of decreasing the initial splashing.

No. 11 is an example in which the temperature of melting the Al—Ni—Cu—La alloy is low and, since the nozzle was clogged in the spray forming, the spray forming was discontinued and, accordingly, subsequent measurement for the Vickers hardness and evaluation for the initial splashing could not be performed.

No. 15 is an example in which the temperature of melting the Al—Ni—Cu—La alloy is high. Since the Vickers hardness is low, it has no effect of decreasing the initial splashing.

No. 16 is an example in which the gas/metal ratio in the step of gas atomizing the molten metal of the Al—Ni—Cu—La alloy is low. Since the Vickers hardness is low, it has no effect of decreasing the initial splashing.

No. 20 is an example in which the spray distance is short in the step of depositing the Al—Ni—Cu—La alloy on the collector and, since the Vickers hardness is low, it has no effect of decreasing the initial splashing.

No. 24 is an example in which the spray distance is long in the step of depositing the Al—Ni—Cu—La alloy on the collector in which lowering of the yield occurred in spray forming. Accordingly, it could not be served to subsequent steps, and measurement for the Vickers hardness and evaluation for the initial splashing could not be performed.

No. 28 is an example of performing plastic working (rolling) at a high temperature. Since the Vickers hardness is low, it has no effect of decreasing the initial splashing.

No. 29 is an example of performing heat treatment or annealing at a low temperature. Strains caused by the plastic working (rolling) could not be removed and it was difficult so as to have a desired size and shape by the subsequent machining. Accordingly, subsequent evaluation for the initial splashing could not be performed.

No. 33 is an example of performing heat treatment or annealing at a high temperature. Since the Vickers hardness is low, it has no effect of decreasing the initial splashing.

### Example 2

Next, Al-based alloy sputtering targets (specimens) were manufactured in the same manner as in Example 1 (except the conditions shown in Tables 3 and 4) by using the Al—Co—Ge—La alloys as shown in Tables 3 and 4 (Nos. 34 to 66). The Vickers hardness (HV) was measured for the Al-based sputtering targets obtained, and the generation of initial splashing was evaluated by conducting the sputtering test.

TABLE 3

| | | | | | | | | | | Number of | |
|---|---|---|---|---|---|---|---|---|---|---|---|
| | | | | | | | | Temperature | | generation | Pass/failure |
| | | | | | | | | of heat | | of initial | judgment for |
| | | | | Melting | Gas/Metal | Spray | Rolling | treatment or | Vickers | splashing | decreasing |
| | Co | Ge | La | temperature | ratio | distance | temperature | annealing | hardness | (Number/ | initial |
| No. | (at %) | (at %) | (at %) | (° C.) | (Nm³/kg) | (mm) | (° C.) | (° C.) | (HV) | cm²) | splashing |
| 34 | 0.05 | 0.5 | 0.2 | 950 | 8 | 1000 | 400 | 250 | 38.3 | 7 | A |
| 35 | 0.2 | 0.5 | 0.2 | 950 | 8 | 1000 | 400 | 250 | 42.5 | 5 | A |
| 36 | 1.0 | 0.5 | 0.2 | 950 | 8 | 1000 | 400 | 250 | 47.7 | 3 | A |
| 37 | 1.5 | 0.5 | 0.2 | 950 | 8 | 1000 | 400 | 250 | 51.6 | 2 | A |
| 38 | 0.2 | 0.1 | 0.2 | 950 | 8 | 1000 | 400 | 250 | 36.8 | 7 | A |
| 39 | 0.2 | 0.5 | 0.2 | 950 | 8 | 1000 | 400 | 250 | 42.5 | 5 | A |
| 40 | 0.2 | 1.0 | 0.2 | 950 | 8 | 1000 | 400 | 250 | 44.3 | 4 | A |
| 41 | 0.2 | 0.5 | 0.1 | 950 | 8 | 1000 | 400 | 250 | 39.4 | 6 | A |
| 42 | 0.2 | 0.5 | 0.2 | 950 | 8 | 1000 | 400 | 250 | 42.5 | 5 | A |
| 43 | 0.2 | 0.5 | 1.0 | 950 | 8 | 1000 | 400 | 250 | 49.2 | 2 | A |
| 44 | 0.2 | 0.5 | 0.2 | 800 | | 1000 | | | | | |
| 45 | 0.2 | 0.5 | 0.2 | 850 | 8 | 1000 | 400 | 250 | 42.7 | 5 | A |
| 46 | 0.2 | 0.5 | 0.2 | 950 | 8 | 1000 | 400 | 250 | 42.5 | 5 | A |
| 47 | 0.2 | 0.5 | 0.2 | 1000 | 8 | 1000 | 400 | 250 | 42.4 | 5 | A |
| 48 | 0.2 | 0.5 | 0.2 | 1100 | 8 | 1000 | 400 | 250 | 26.6 | 31 | B |
| 49 | 0.2 | 0.5 | 0.2 | 950 | 5 | 1000 | 400 | 250 | 25.2 | 34 | B |
| 50 | 0.2 | 0.5 | 0.2 | 950 | 6 | 1000 | 400 | 250 | 40.8 | 6 | A |
| 51 | 0.2 | 0.5 | 0.2 | 950 | 7 | 1000 | 400 | 250 | 42.0 | 6 | A |
| 52 | 0.2 | 0.5 | 0.2 | 950 | 8 | 1000 | 400 | 250 | 42.5 | 5 | A |

TABLE 4

| | | | | | | | | | | Number of | |
|---|---|---|---|---|---|---|---|---|---|---|---|
| | | | | | | | | Temperature | | generation | Pass/failure |
| | | | | | | | | of heat | | of initial | judgment for |
| | | | | Melting | Gas/Metal | Spray | Rolling | treatment or | Vickers | splashing | decreasing |
| | Co | Ge | La | temperature | ratio | distance | temperature | annealing | hardness | (Number/ | initial |
| No. | (at %) | (at %) | (at %) | (° C.) | (Nm³/kg) | (mm) | (° C.) | (° C.) | (HV) | cm²) | splashing |
| 53 | 0.2 | 0.5 | 0.2 | 950 | 8 | 800 | 400 | 250 | 27.5 | 29 | B |
| 54 | 0.2 | 0.5 | 0.2 | 950 | 8 | 900 | 400 | 250 | 43.1 | 4 | A |
| 55 | 0.2 | 0.5 | 0.2 | 950 | 8 | 1000 | 400 | 250 | 42.5 | 5 | A |
| 56 | 0.2 | 0.5 | 0.2 | 950 | 8 | 1200 | 400 | 250 | 42.0 | 5 | A |
| 57 | 0.2 | 0.5 | 0.2 | 950 | 8 | 1300 | | | | | |
| 58 | 0.2 | 0.5 | 0.2 | 950 | 8 | 1000 | 350 | 250 | 41.1 | 6 | A |
| 59 | 0.2 | 0.5 | 0.2 | 950 | 8 | 1000 | 400 | 250 | 42.5 | 5 | A |
| 60 | 0.2 | 0.5 | 0.2 | 950 | 8 | 1000 | 450 | 250 | 41.3 | 6 | A |
| 61 | 0.2 | 0.5 | 0.2 | 950 | 8 | 1000 | 480 | 250 | 24.4 | 36 | B |
| 62 | 0.2 | 0.5 | 0.2 | 950 | 8 | 1000 | 400 | 50 | 48.8 | | |
| 63 | 0.2 | 0.5 | 0.2 | 950 | 8 | 1000 | 400 | 100 | 45.6 | 4 | A |
| 64 | 0.2 | 0.5 | 0.2 | 950 | 8 | 1000 | 400 | 250 | 42.5 | 5 | A |
| 65 | 0.2 | 0.5 | 0.2 | 950 | 8 | 1000 | 400 | 300 | 41.7 | 5 | A |
| 66 | 0.2 | 0.5 | 0.2 | 950 | 8 | 1000 | 400 | 350 | 25.4 | 33 | B |

In Tables 3 and 4, contents of elements are shown as Co (at %) for the content of Co element (atomic %), as Ge (at %) for the content of Ge element (atomic %), and as La (at %) for the content of La element (atomic %), respectively. From Tables 3 and 4, the followings can be recognized. In Nos. 34 to 43, 45 to 47, 50 to 52, 54 to 56, 58 to 60 and 63 to 65, since the Vickers hardness (HV) of the Al—Co—Ge—La alloy sputtering target is controlled properly, the number of generation of the initial splashing remains to less than 8 Number/cm² and they have an effect of decreasing the initial splashing.

On the contrary, in the specimens having not appropriate Vickers hardness (HV), the number of generation of the splashing is 8 Number/cm² or more by the following reason respective and it cannot be said that they have the effect of decreasing the initial splashing.

No. 44 is an example in which the temperature of melting the Al—Co—Ge—La alloy is low and, since the nozzle was clogged in the spray forming, the spray forming was discontinued and, accordingly, subsequent measurement for the Vickers hardness and evaluation for the initial splashing could not be performed.

No. 48 is an example in which the temperature of melting the Al—Co—Ge—La alloy is high. Since the Vickers hardness is low, it has no effect of decreasing the initial splashing.

No. 49 is an example in which the gas/metal ratio in the step of gas atomizing the molten metal of the Al—Co—Ge—La alloy is low. Since the Vickers hardness is low, it has no effect of decreasing the initial splashing.

No. 53 is an example in which the spray distance is short in the step of depositing the Al—Co—Ge—La alloy on the collector and, since the Vickers hardness is low, it has no effect of decreasing the initial splashing.

No. 57 is an example in which the spray distance is long in the step of depositing the Al—Co—Ge—La alloy on the collector in which lowering of the yield occurred in spray forming. Accordingly, it could not be served to subsequent steps, and measurement for the Vickers hardness and evaluation for the initial splashing could not be performed.

No. 61 is an example of performing plastic working (rolling) at a high temperature. Since the Vickers hardness is low, it has no effect of decreasing the initial splashing.

No. 62 is an example of performing heat treatment or annealing at a low temperature. Strains caused by the plastic working (rolling) could not be removed and it was difficult to finish so as to have a desired size and shape by the subsequent machining. Accordingly, subsequent evaluation for the initial splashing could not be performed.

No. 66 is an example of performing heat treatment or annealing at a high temperature. Since the Vickers hardness is low, it has no effect of decreasing the initial splashing.

### Example 3

Next, Al-based alloy sputtering targets (specimens) were manufactured in the same manner as in Example 1 (except the conditions shown in Tables 5 and 6) by using the Al—Ni—Ge—Nd alloys as shown in Tables 5 and 6 (Nos. 67 to 99). The Vickers hardness (HV) was measured for the Al-based sputtering targets obtained, and the generation of initial splashing was evaluated by conducting the sputtering test.

TABLE 5

| | | | | | | | | | | Number of | |
|---|---|---|---|---|---|---|---|---|---|---|---|
| | | | | | | | | Temperature | | generation | Pass/failure |
| | | | | | | | | of heat | | of initial | judgment for |
| | | | | Melting | Gas/Metal | Spray | Rolling | treatment or | Vickers | splashing | decreasing |
| | Ni | Ge | Nd | temperature | ratio | distance | temperature | annealing | hardness | (Number/ | initial |
| No. | (at %) | (at %) | (at %) | (° C.) | (Nm³/kg) | (mm) | (° C.) | (° C.) | (HV) | cm²) | splashing |
| 67 | 0.05 | 0.5 | 0.5 | 950 | 8 | 1000 | 400 | 250 | 40.1 | 6 | A |
| 68 | 0.1 | 0.5 | 0.5 | 950 | 8 | 1000 | 400 | 250 | 41.4 | 5 | A |
| 69 | 1.0 | 0.5 | 0.5 | 950 | 8 | 1000 | 400 | 250 | 53.9 | 1 | A |
| 70 | 1.5 | 0.5 | 0.5 | 950 | 8 | 1000 | 400 | 250 | 56.0 | 1 | A |
| 71 | 0.1 | 0.1 | 0.5 | 950 | 8 | 1000 | 400 | 250 | 37.5 | 7 | A |
| 72 | 0.1 | 0.5 | 0.5 | 950 | 8 | 1000 | 400 | 250 | 41.4 | 5 | A |
| 73 | 0.1 | 1.0 | 0.5 | 950 | 8 | 1000 | 400 | 250 | 46.1 | 4 | A |
| 74 | 0.1 | 0.5 | 0.1 | 950 | 8 | 1000 | 400 | 250 | 36.4 | 7 | A |
| 75 | 0.1 | 0.5 | 0.5 | 950 | 8 | 1000 | 400 | 250 | 41.4 | 5 | A |
| 76 | 0.1 | 0.5 | 1.0 | 950 | 8 | 1000 | 400 | 250 | 47.8 | 3 | A |
| 77 | 0.1 | 0.5 | 0.5 | 800 | | 1000 | | | | | |
| 78 | 0.1 | 0.5 | 0.5 | 850 | 8 | 1000 | 400 | 250 | 41.8 | 5 | A |
| 79 | 0.1 | 0.5 | 0.5 | 950 | 8 | 1000 | 400 | 250 | 41.4 | 5 | A |
| 80 | 0.1 | 0.5 | 0.5 | 1000 | 8 | 1000 | 400 | 250 | 41.0 | 6 | A |
| 81 | 0.1 | 0.5 | 0.5 | 1100 | 8 | 1000 | 400 | 250 | 25.1 | 33 | B |
| 82 | 0.1 | 0.5 | 0.5 | 950 | 5 | 1000 | 400 | 250 | 24.3 | 35 | B |
| 83 | 0.1 | 0.5 | 0.5 | 950 | 6 | 1000 | 400 | 250 | 40.2 | 6 | A |
| 84 | 0.1 | 0.5 | 0.5 | 950 | 7 | 1000 | 400 | 250 | 40.7 | 6 | A |
| 85 | 0.1 | 0.5 | 0.5 | 950 | 8 | 1000 | 400 | 250 | 41.4 | 5 | A |

TABLE 6

| | | | | | | | | | | Number of | |
|---|---|---|---|---|---|---|---|---|---|---|---|
| | | | | | | | | Temperature | | generation | Pass/failure |
| | | | | | | | | of heat | | of initial | judgment for |
| | | | | Melting | Gas/Metal | Spray | Rolling | treatment or | Vickers | splashing | decreasing |
| | Ni | Ge | Nd | temperature | ratio | distance | temperature | annealing | hardness | (Number/ | initial |
| No. | (at %) | (at %) | (at %) | (° C.) | (Nm³/kg) | (mm) | (° C.) | (° C.) | (HV) | cm²) | splashing |
| 86 | 0.1 | 0.5 | 0.5 | 950 | 8 | 800 | 400 | 250 | 26.4 | 30 | B |
| 87 | 0.1 | 0.5 | 0.5 | 950 | 8 | 900 | 400 | 250 | 41.8 | 5 | A |
| 88 | 0.1 | 0.5 | 0.5 | 950 | 8 | 1000 | 400 | 250 | 41.4 | 5 | A |
| 89 | 0.1 | 0.5 | 0.5 | 950 | 8 | 1200 | 400 | 250 | 41.7 | 5 | A |
| 90 | 0.1 | 0.5 | 0.5 | 950 | 8 | 1300 | | | | | |
| 91 | 0.1 | 0.5 | 0.5 | 950 | 8 | 1000 | 350 | 250 | 39.8 | 6 | A |
| 92 | 0.1 | 0.5 | 0.5 | 950 | 8 | 1000 | 400 | 250 | 41.4 | 5 | A |
| 93 | 0.1 | 0.5 | 0.5 | 950 | 8 | 1000 | 450 | 250 | 40.3 | 6 | A |
| 94 | 0.1 | 0.5 | 0.5 | 950 | 8 | 1000 | 480 | 250 | 23.9 | 36 | B |
| 95 | 0.1 | 0.5 | 0.5 | 950 | 8 | 1000 | 400 | 50 | 47.6 | | |
| 96 | 0.1 | 0.5 | 0.5 | 950 | 8 | 1000 | 400 | 100 | 43.2 | 4 | A |
| 97 | 0.1 | 0.5 | 0.5 | 950 | 8 | 1000 | 400 | 250 | 41.4 | 5 | A |
| 98 | 0.1 | 0.5 | 0.5 | 950 | 8 | 1000 | 400 | 300 | 40.6 | 6 | A |
| 99 | 0.1 | 0.5 | 0.5 | 950 | 8 | 1000 | 400 | 350 | 25.2 | 33 | B |

In Tables 5 and 6, contents of elements are shown as Ni (at %) for the content of Ni element (atomic %), as Ge (at %) for the content of Ge element (atomic %), and as Nd (at %) for the content of Nd element (atomic %), respectively. From Tables 5 and 6, the followings can be recognized. In Nos. 67 to 76, 78 to 80, 83 to 85, 87 to 89, 91 to 93 and 96 to 98, since the Vickers hardness (HV) of the Al—Ni—Ge—Nd alloy sputtering target is controlled properly, the number of generation of the initial splashing remains to less than 8 Number/cm² and they have an effect of decreasing the initial splashing.

On the contrary, in the specimens having not appropriate Vickers hardness (HV), the number of generation of the splashing is 8 Number/cm² or more by the following reason respective and it cannot be said that they have the effect of decreasing the initial splashing.

No. 77 is an example in which the temperature of melting the Al—Ni—Ge—Nd alloy is low and, since the nozzle was clogged in the spray forming, the spray forming was discontinued and, accordingly, subsequent measurement for the Vickers hardness and evaluation for the initial splashing could not be performed.

No. 81 is an example in which the temperature of melting the Al—Ni—Ge—Nd alloy is high. Since the Vickers hardness is low, it has no effect of decreasing the initial splashing.

No. 82 is an example in which the gas/metal ratio in the step of gas atomizing the molten metal of the Al—Ni—Ge—Nd alloy is low. Since the Vickers hardness is low, it has no effect of decreasing the initial splashing.

No. 86 is an example in which the spray distance is short in the step of depositing the Al—Ni—Ge—Nd alloy on the collector and, since the Vickers hardness is low, it has no effect of decreasing the initial splashing.

No. 90 is an example in which the spray distance is long in the step of depositing the Al—Ni—Ge—Nd alloy on the collector in which lowering of the yield occurred in spray forming. Accordingly, it could not be served to subsequent steps, and measurement for the Vickers hardness and evaluation for the initial splashing could not be performed.

No. 94 is an example of performing plastic working (rolling) at a high temperature. Since the Vickers hardness is low, it has no effect of decreasing the initial splashing.

No. 95 is an example of performing heat treatment or annealing at a low temperature. Strains caused by the plastic working (rolling) could not be removed and it was difficult to finish so as to have a desired size and shape by the subsequent machining. Accordingly, subsequent evaluation for the initial splashing could not be performed.

No. 99 is an example of performing heat treatment or annealing at a high temperature. Since the Vickers hardness is low, it has no effect of decreasing the initial splashing.

### Example 4

Next, Al-based alloy sputtering targets (specimens) were manufactured in the same manner as in Example 1 (except the conditions shown in Tables 7 and 8) by using the Al—Co—Ge—Nd alloys as shown in Tables 7 and 8 (Nos. 100 to 132). The Vickers hardness (HV) was measured for the Al-based sputtering targets obtained, and the generation of initial splashing was evaluated by conducting the sputtering test.

TABLE 7

| | | | | | | | | | | Number of | |
|---|---|---|---|---|---|---|---|---|---|---|---|
| | | | | | | | | Temperature | | generation | Pass/failure |
| | | | | | | | | of heat | | of initial | judgment for |
| | | | | Melting | Gas/Metal | Spray | Rolling | treatment or | Vickers | splashing | decreasing |
| | Co | Ge | Nd | temperature | ratio | distance | temperature | annealing | hardness | (Number/ | initial |
| No. | (at %) | (at %) | (at %) | (° C.) | (Nm³/kg) | (mm) | (° C.) | (° C.) | (HV) | cm²) | splashing |
| 100 | 0.05 | 0.5 | 0.3 | 950 | 8 | 1000 | 400 | 250 | 42.8 | 7 | A |
| 101 | 0.1 | 0.5 | 0.3 | 950 | 8 | 1000 | 400 | 250 | 43.3 | 4 | A |
| 102 | 1.0 | 0.5 | 0.3 | 950 | 8 | 1000 | 400 | 250 | 52.2 | 2 | A |
| 103 | 1.5 | 0.5 | 0.3 | 950 | 8 | 1000 | 400 | 250 | 57.1 | 1 | A |
| 104 | 0.1 | 0.1 | 0.3 | 950 | 8 | 1000 | 400 | 250 | 39.3 | 6 | A |
| 105 | 0.1 | 0.5 | 0.3 | 950 | 8 | 1000 | 400 | 250 | 43.3 | 5 | A |
| 106 | 0.1 | 1.0 | 0.3 | 950 | 8 | 1000 | 400 | 250 | 48.2 | 3 | A |
| 107 | 0.1 | 0.5 | 0.1 | 950 | 8 | 1000 | 400 | 250 | 41.3 | 5 | A |
| 108 | 0.1 | 0.5 | 0.3 | 950 | 8 | 1000 | 400 | 250 | 43.3 | 4 | A |
| 109 | 0.1 | 0.5 | 1.0 | 950 | 8 | 1000 | 400 | 250 | 50.2 | 2 | A |
| 110 | 0.1 | 0.5 | 0.3 | 800 | | 1000 | | | | | |
| 111 | 0.1 | 0.5 | 0.3 | 850 | 8 | 1000 | 400 | 250 | 43.5 | 4 | A |
| 112 | 0.1 | 0.5 | 0.3 | 950 | 8 | 1000 | 400 | 250 | 43.3 | 4 | A |
| 113 | 0.1 | 0.5 | 0.3 | 1000 | 8 | 1000 | 400 | 250 | 43.2 | 5 | A |
| 114 | 0.1 | 0.5 | 0.3 | 1100 | 8 | 1000 | 400 | 250 | 27.4 | 30 | B |
| 115 | 0.1 | 0.5 | 0.3 | 950 | 5 | 1000 | 400 | 250 | 26.2 | 35 | B |
| 116 | 0.1 | 0.5 | 0.3 | 950 | 6 | 1000 | 400 | 250 | 41.6 | 5 | A |
| 117 | 0.1 | 0.5 | 0.3 | 950 | 7 | 1000 | 400 | 250 | 42.8 | 6 | A |
| 118 | 0.1 | 0.5 | 0.3 | 950 | 8 | 1000 | 400 | 250 | 43.3 | 4 | A |

TABLE 8

| | | | | | | | | | | Number of | |
|---|---|---|---|---|---|---|---|---|---|---|---|
| | | | | | | | | Temperature | | generation | Pass/failure |
| | | | | | | | | of heat | | of initial | judgment for |
| | | | | Melting | Gas/Metal | Spray | Rolling | treatment or | Vickers | splashing | decreasing |
| | Co | Ge | Nd | temperature | ratio | distance | temperature | annealing | hardness | (Number/ | initial |
| No. | (at %) | (at %) | (at %) | (° C.) | (Nm³/kg) | (mm) | (° C.) | (° C.) | (HV) | cm²) | splashing |
| 119 | 0.1 | 0.5 | 0.3 | 950 | 8 | 800 | 400 | 250 | 28.3 | 28 | B |
| 120 | 0.1 | 0.5 | 0.3 | 950 | 8 | 900 | 400 | 250 | 43.9 | 3 | A |
| 121 | 0.1 | 0.5 | 0.3 | 950 | 8 | 1000 | 400 | 250 | 43.3 | 5 | A |
| 122 | 0.1 | 0.5 | 0.3 | 950 | 8 | 1200 | 400 | 250 | 42.8 | 4 | A |
| 123 | 0.1 | 0.5 | 0.3 | 950 | 8 | 1300 | | | | | |
| 124 | 0.1 | 0.5 | 0.3 | 950 | 8 | 1000 | 350 | 250 | 41.7 | 5 | A |
| 125 | 0.1 | 0.5 | 0.3 | 950 | 8 | 1000 | 400 | 250 | 43.3 | 4 | A |
| 126 | 0.1 | 0.5 | 0.3 | 950 | 8 | 1000 | 450 | 250 | 42.1 | 6 | A |
| 127 | 0.1 | 0.5 | 0.3 | 950 | 8 | 1000 | 480 | 250 | 25.2 | 35 | B |
| 128 | 0.1 | 0.5 | 0.3 | 950 | 8 | 1000 | 400 | 50 | 49.6 | | |
| 129 | 0.1 | 0.5 | 0.3 | 950 | 8 | 1000 | 400 | 100 | 46.4 | 3 | A |
| 130 | 0.1 | 0.5 | 0.3 | 950 | 8 | 1000 | 400 | 250 | 43.3 | 4 | A |
| 131 | 0.1 | 0.5 | 0.3 | 950 | 8 | 1000 | 400 | 300 | 42.5 | 5 | A |
| 132 | 0.1 | 0.5 | 0.3 | 950 | 8 | 1000 | 400 | 350 | 26.2 | 33 | B |

In Tables 7 and 8, contents of elements are shown as Co (at %) for the content of Co element (atomic %), as Ge (at %) for the content of Ge element (atomic %), and as Nd (at %) for the content of Nd element (atomic %), respectively. From Tables 7 and 8, the followings can be recognized. In Nos. 100 to 109, 111 to 113, 116 to 118, 120 to 122, 124 to 126 and 129 to 131, since the Vickers hardness (HV) of the Al—Co—Ge—Nd alloy sputtering target is controlled properly, the number of generation of the initial splashing remains to less than 8 Number/cm² and they have an effect of decreasing the initial splashing.

On the contrary, in the specimens having not appropriate Vickers hardness (HV), the number of generation of the splashing is 8 Number/cm² or more by the following reason respective and it cannot be said that they have the effect of decreasing the initial splashing.

No. 110 is an example in which the temperature of melting the Al—Co—Ge—Nd alloy is low and, since the nozzle was clogged in the spray forming, the spray forming was discontinued and, accordingly, subsequent measurement for the Vickers hardness and evaluation for the initial splashing could not be performed.

No. 114 is an example in which the temperature of melting the Al—Co—Ge—Nd alloy is high. Since the Vickers hardness is low, it has no effect of decreasing the initial splashing.

No. 115 is an example in which the gas/metal ratio in the step of gas atomizing the molten metal of the Al—Co—Ge—Nd alloy is low. Since the Vickers hardness is low, it has no effect of decreasing the initial splashing.

No. 119 is an example in which the spray distance is short in the step of depositing the Al—Co—Ge—Nd alloy on the collector and, since the Vickers hardness is low, it has no effect of decreasing the initial splashing.

No. 123 is an example in which the spray distance is long in the step of depositing the Al—Co—Ge—Nd alloy on the collector in which lowering of the yield occurred in spray forming. Accordingly, it could not be served to subsequent steps, and measurement for the Vickers hardness and evaluation for the initial splashing could not be performed.

No. 127 is an example of performing plastic working (rolling) at a high temperature. Since the Vickers hardness is low, it has no effect of decreasing the initial splashing.

No. 128 is an example of performing heat treatment or annealing at a low temperature. Strains caused by the plastic working (rolling) could not be removed and it was difficult to finish so as to have a desired size and shape by the subsequent machining. Accordingly, subsequent evaluation for the initial splashing could not be performed.

No. 132 is an example of performing heat treatment or annealing at a high temperature. Since the Vickers hardness is low, it has no effect of decreasing the initial splashing.

1. An Al-based alloy sputtering target comprising;
at least one element selected from the group A consisting of Ni and Co,
at least one element selected from the group B consisting of Cu and Ge, and
at least one element selected from the group C consisting of La, Gd, and Nd,
wherein a hardness of the Al-based alloy sputtering target is 35 or more as a Vickers hardness (HV).

2. The Al-based alloy sputtering target according to claim 1, wherein a total content of the group A is 0.05 atomic % or more and 1.5 atomic % or less,
a total content of the group B is 0.1 atomic % or more and 1 atomic % or less, and
a total content of the group C is 0.1 atomic % or more and 1 atomic % or less.

3. The Al-based alloy sputtering target according to claim 1, wherein only Ni is selected from the group A, only Cu is selected from the group B, and only La is selected from the group C.

4. The Al-based alloy sputtering target according to claim 2, wherein only Ni is selected from the group A, only Cu is selected from the group B, and only La is selected from the group C.

5. A method of manufacturing an Al-based alloy sputtering target comprising:
obtaining a molten metal at 850 to 1000° C. of an Al-based alloy comprising:
a group A consisting of Ni and Co in a total amount of 0.05 atomic % or more and 1.5 atomic % or less,
a group B consisting of Cu and Ge in a total amount of 0.1 atomic % or more and 1 atomic % or less, and
a group C consisting of La, Gd, and Nd in a total amount of 0.1 atomic % or more and 1 atomic % or less;
gas-atomizing the molten metal at a gas/metal ratio of 6 Nm³/kg or more to refine the Al-based alloy;
depositing the refined Al-based alloy on a collector under a condition of a spray distance of from 900 to 1200 mm to obtain a perform;
densifying the preform by a densifying means to obtain a dense body;
subjecting the dense body to plastic working at 450° C. or lower; and
subjecting the dense body after plastic working to heat treatment or annealing at 100 to 300° C.

6. The method of manufacturing an Al-based alloy sputtering target according to claim 5, wherein only Ni is selected from the group A, only Cu is selected from the group B, and only La is selected from the group C.

7. The Al-based alloy sputtering target according to claim 1, wherein only Co is selected from the group A, only Ge is selected from the group B, and only La is selected from the group C.

8. The Al-based alloy sputtering target according to claim 2, wherein only Co is selected from the group A, only Ge is selected from the group B, and only La is selected from the group C.

9. The method of manufacturing an Al-based alloy sputtering target according to claim 5, wherein only Co is selected from the group A, only Ge is selected from the group B, and only La is selected from the group C.

10. The Al-based alloy sputtering target according to claim 1, wherein only Ni is selected from the group A, only Ge is selected from the group B, and only Nd is selected from the group C.

11. The Al-based alloy sputtering target according to claim 2, wherein only Ni is selected from the group A, only Ge is selected from the group B, and only Nd is selected from the group C.

12. The method of manufacturing an Al-based alloy sputtering target according to claim 5, wherein only Ni is selected from the group A, only Ge is selected from the group B, and only Nd is selected from the group C.

13. The Al-based alloy sputtering target according to claim 1, wherein only Co is selected from the group A, only Ge is selected from the group B, and only Nd is selected from the group C.

14. The Al-based alloy sputtering target according to claim 2, wherein only Co is selected from the group A, only Ge is selected from the group B, and only Nd is selected from the group C.

15. The method of manufacturing an Al-based alloy sputtering target according to claim 5, wherein only Co is selected from the group A, only Ge is selected from the group B, and only Nd is selected from the group C.
